(19) United States
(12) Patent Application Publication
(10) Pub. No.: US 2024/0162925 A1
(43) Pub. Date: May 16, 2024

(54) METHOD AND ARRANGEMENTS FOR SUPPORTING INTERMODULATON COMPONENT SUPPRESSION IN A TRANSMITTER SYSTEM WITH DIGITAL PREDISTORTION AND FEEDFORWARD LINEARIZATION

(71) Applicant: Telefonaktiebolaget LM Ericsson (publ), Stockholm (SE)

(72) Inventors: Peter SCOTT, Stockholm (SE); David SCAFE, Sundbyberg (SE); S M Shahrear TANZIL, Ottawa (CA); Ashim BISWAS, Sollentuna (SE)

(21) Appl. No.: 18/550,529

(22) PCT Filed: Mar. 26, 2021
(86) PCT No.: PCT/SE2021/050268

§ 371 Date: Sep. 14, 2023

(51) Int. Cl. H04B 1/04; H03F 1/32; H03F 3/24

(52) U.S. Cl. CPC H04B 1/0475; H03F 1/3223; H03F 1/3258; H03F 3/245; H03F 2200/451; H04B 2001/0425

(57) ABSTRACT

Supporting suppression of distortion caused by a power amplifier, “PA”, included in a transmitter system configured to perform digital predistortion, “DPD”, and feedforward, “FF”, linearization on multiple digital input signals relating to different frequency bands, respectively. The PA is used for power amplification in preparation for transmission by a wireless communication network and is operative with an instantaneous bandwidth, “IBW’”. Information is obtained identifying one or more intermodulation, “IM”, components outside the frequency bands but within the IBW, and caused by said PA. The identified IM components are selectively processed as part of said DPD to thereby suppress formation of at least some of the identified IM components, and/or as part of the FF linearization by adding reference signals to the FF linearization, which reference signals correspond to at least some of the identified IM components.

### TECHNICAL FIELD

Embodiments herein concern a method and devices(s) for performing digital predistortion (DPD) and feedforward (FF) linearization on multiple digital input signals relating to different frequency bands, respectively, in order to condition said signals before transmission in said frequency bands by a wireless communication network.

### BACKGROUND

Communication devices such as wireless communication devices, that simply may be named wireless devices, may also be known as e.g. user equipments (UEs), mobile terminals, wireless terminals and/or mobile stations. A wireless device is enabled to communicate wirelessly in a wireless communication network, wireless communication system, or radio communication system, e.g. a telecommunication network, sometimes also referred to as a cellular radio system, cellular network or cellular communication system. The communication may be performed e.g. between two wireless devices, between a wireless device and a regular telephone and/or between a wireless device and a server via a Radio Access Network (RAN) and possibly one or more core networks, comprised within the cellular communication network. The wireless device may further be referred to as a mobile telephone, cellular telephone, laptop, Personal Digital Assistant (PDA), tablet computer, just to mention some further examples. Wireless devices may be so called Machine to Machine (M2M) devices or Machine Type of Communication (MTC) devices, i.e. devices that are not associated with a conventional user.

The wireless device may be, for example, portable, pocket-storable, hand-held, computer-comprised, or vehicle-mounted mobile device, enabled to communicate voice and/or data, via the RAN, with another entity, such as another wireless device or a server.

The wireless communication network may cover a geographical area which is divided into cell areas, wherein each cell area is served by at least one base station, or Base Station (BS), e.g. a Radio Base Station (RBS), which sometimes may be referred to as e.g. “eNB”, “eNodeB”, “NodeB”, “B node”, “gNB”, or BTS (Base Transceiver Station), depending on the technology and terminology used. The base stations may be of different classes such as e.g. macro eNodeB, home eNodeB or pico base station, based on transmission power and thereby also cell size. A cell is typically identified by one or more cell identities. The base station at a base station site may provide radio coverage for one or more cells. A cell is thus typically associated with a geographical area where radio coverage for that cell is provided by the base station at the base station site. Cells may overlap so that several cells cover the same geographical area. By the base station providing or serving a cell is typically meant that the base station provides radio coverage such that one or more wireless devices located in the geographical area where the radio coverage is provided may be served by the base station in said cell. When a wireless device is said to be served in or by a cell this implies that the wireless device is served by the base station providing radio coverage for the cell. One base station may serve one or several cells. Further, each base station may support one or several communication technologies. The base stations communicate over the air interface operating on radio frequencies with the wireless device within range of the base stations.

In some RANs, several base stations may be connected, e.g. by landlines or microwave, to a radio network controller, e.g. a Radio Network Controller (RNC) in Universal Mobile Telecommunication System (UMTS), and/or to each other. The radio network controller, also sometimes termed a Base Station Controller (BSC) e.g. in GSM, may supervise and coordinate various activities of the plural base stations connected thereto. GSM is an abbreviation for Global System for Mobile Communication (originally: Groupe Spécial Mobile), which may be referred to as 2nd generation or 2G.

UMTS is a third generation mobile communication system, which may be referred to as 3rd generation or 3G, and which evolved from the GSM, and provides improved mobile communication services based on Wideband Code Division Multiple Access (WCDMA) access technology. UMTS Terrestrial Radio Access Network (UTRAN) is essentially a radio access network using wideband code division multiple access for wireless devices. High Speed Packet Access (HSPA) is an amalgamation of two mobile telephony protocols, High Speed Downlink Packet Access (HSDPA) and High Speed Uplink Packet Access (HSUPA), defined by 3GPP, that extends and improves the performance of existing 3rd generation mobile telecommunication networks utilizing the WCDMA. Such networks may be named WCDMA/HSPA.

The expression downlink (DL) may be used for the transmission path from the base station to the wireless device. The expression uplink (UL) may be used for the transmission path in the opposite direction i.e. from the wireless device to the base station.

In 3rd Generation Partnership Project (3GPP) Long Term Evolution (LTE), base stations, which may be referred to as eNodeBs or eNBs, may be directly connected to other base stations and may be directly connected to one or more core networks. LTE may be referred to as 4th generation or 4G.

The 3GPP has undertaken to evolve further the UTRAN and GSM based radio access network technologies, for example into evolved UTRAN (E-UTRAN) used in LTE.

3GPP has specified and development work continues with a fifth generation (5G) wide are wireless communication networks, and even development with a further generation has begun.

Ultra-wideband radios supporting multiple frequency bands are of increasing interest. The requirements for such in case of instantaneous bandwidths (IBW) of about 1 GHz and above are particularly difficult to fulfil. For dual-band and triple-band products with IBW around 400 to 800 MHz, conventional methods are still feasible with some adaptation. However, for IBW of 1 GHz and above those are typically not only insufficient in terms of performance but would typically also require very costly hardware resources. In other words, even if some conventional methods of radio design and implementation could work for such IBWs, they would result in very costly implementations.

As used herein, instantaneous bandwidth, or IBW, can be considered the frequency range from lowest to highest frequency of the signals subject to the power amplification, i.e. of the signals that instantaneously are to be power amplified, typically corresponding to a total bandwidth that the power amplifier is to be used with. The instantaneous bandwidth, in terms of predefined frequency bands that a PA shall be able to handle instantaneously, may correspond to a frequency range stretching from the lowest frequency of the lowest such frequency band to the highest frequency of the highest such frequency band. Predefined frequency bands are e.g. specified by 3GPP, where operating bands are defined in 3GPP TS 3x.101, in the case of LTE it is defined in ETSI TS136.101 and for 5G it in TS138.101.

Since the signals within the IBW and that are to be power amplified typically are spaced apart and belongs to spaced-apart frequency bands, i.e. non-contiguous frequency bands, and these signals and frequency bands are not continuously filling up the IBW, there is typically a lot of space within the IBW without signals to be power amplified. In these spaces it is desirable, or even required, that the power amplification results in no, or very small, amounts of noise or spurious signals, e.g. due to intermodulation and non-linearities of the PA. A conventional design that would attempt to handle a whole IBW “as is” for a wideband system, e.g. with IBW>1 GHz, would not be efficient or practically feasible. Still, the IBWs desirable to handle are increasing with increased number of new and different wireless communication systems being employed, and further and additional higher frequencies and frequency bands that these systems rely on are being used. In other words, it is in general desirable to find new ways of handling PA with large IBWs and that enable more efficient implementations than conventionally.

FIGS. 1A-B show an example of non-contiguous multiband signals for a wideband system with e.g. IBW>1 GHz. As can be seen there are 3 non-contiguous frequency bands, one that is being magnified. As illustrated in the figures, e.g. by comparing FIG. 1A with 1B, signals get distorted when passing through the PA, which alternatively may be referred to as High Power Amplifier (HPA) in circumstances relevant herein. The goal of the DPD is to linearize output signals and satisfy 3GPP requirements. The complexity of DPD increases exponentially with the number of input signals typically corresponding to the number of non-contiguous bands. As a result, DPD for multiband, i.e. more than two bands, systems with non-contiguous bands is a challenging problem to solve. Most of the existing DPD methods assume that PA behaviour can be modelled as a Volterra series. DPD which works like the inverse of the PA can be represented as variants of the Volterra series such as generalized memory polynomial, memory polynomial. Once the model has been selected, DPD design mainly focuses on identifying the order of the polynomial, memory taps and their corresponding coefficients. As the number of input signals increases, DPD requires complicated models to linearize PA and often requires higher order polynomial with more memory taps.

FIG. 2 is a schematic block diagram for illustrating an example of a conventional DPD architecture, e.g. for application to single band or multiband signals based on the prior art. Multiband digital baseband data, corresponding to multiband input signals, from previous radio modules are input to a digital upconverter 1. The output of the digital upconverter 1 is then input to a DPD unit 3 comprising a DPD actuator 5 and a DPD adaptor 7. The output of the DPD unit 3 and the DPD performed by the DPD actuator 5, are DPD output signals that correspond to predistorted versions of the input signals, respectively. The output of the DPD unit 3, i.e. the predistorted signals, are input to a radio front end 30 that comprises a radio frequency digital to analogue converter (RF DAC). The resulting analogue signal is then power amplified by a PA 33 and transmitted by an antenna. There is also a radio transmit observation receiver (TOR) 40 that receives the power amplified signal and converts it back to the digital domain to be used for feedback to the DPD adaptor 7 so it can adapt DPD coefficients based on it and provide the DPD coefficients to the DPD actuator 5. The radio TOR 40 comprises a RF analogue to digital converter (RF ADC) 41 and a signal conditioning module 43.

As indicated, one challenging area for multiband radios is the linearization, i.e. to removes effect of non-linearities of the PA and that cause distortion that e.g. manifests as distorted signals and spurious signals. It is a known fact that HPAs generates intermodulation (IM) products, that also may be referred to as IM components, due to inherent nonlinear characteristics. Digital predistortion (DPD) and feedforward (FF) are well known technologies as such that may be used to remove and suppress distortion caused by non-linear characteristics of HPAs, such as intermodulation products caused by this.

An example of a prior art DPD technique can be found in M. Younes, A. Kwan, M. Rawat and F. M. Ghannouchi, “Linearization of Concurrent Tri-Band Transmitters Using 3-D Phase-Aligned Pruned Volterra Model” in IEEE Transactions on Microwave Theory and Techniques, vol. 61, no. 12, pp. 4569-4578, December 2013, doi:10.1109/TMTT.2013.2287176.

An example of a prior art FF solution can be found in US 2016308562 A1.

### SUMMARY

In view of the above, an object is to enable or provide one or more improvements or alternatives in relation to the prior art, such as provide improvements regarding conditioning of multiple digital input signals relating to different frequency bands, respectively, before transmission in said frequency bands by a wireless communication network.

According to a first aspect of embodiments herein, the object is achieved by a method for supporting suppression of distortion caused by a power amplifier (PA) comprised in a transmitter system. The transmitter system being configured to perform digital predistortion (DPD) and feedforward (FF) linearization on multiple digital input signals relating to different frequency bands, respectively, in order to condition said signals before transmission in said frequency bands by a wireless communication network. Said PA is used for power amplification in preparation for said transmission and is operative with an instantaneous bandwidth (IBW) comprising said frequency bands. It is obtained information identifying one or more intermodulation (IM) components outside said frequency bands but within the IBW, which IM components are caused by said PA. Said identified IM components are selectively processed as part of said DPD to thereby suppress formation of at least some of said identified IM components, and/or as part of said FF linearization by adding reference signals to said FF linearization, which additional reference signals correspond to at least some of said identified IM components. As should be realized by the skilled person it can be considered implied that FF linearization in a context as for embodiments already involve reference signals that correspond to said multiple digital input signals and hence said reference signals that correspond to at least some of said identified IM components are additional.

According to a second aspect of embodiments herein, the object is achieved by a computer program comprising instructions that when executed by one or more processors causes one or more apparatuses to perform the method according to the first aspect.

According to a third aspect of embodiments herein, the object is achieved by a carrier comprising the computer program according to the second aspect.

According to a fourth aspect of embodiments herein, the object is achieved by one or more apparatuses for supporting suppression of distortion caused by a PA comprised in a transmitter system. The transmitter system being configured to perform DPD and FF linearization on multiple digital input signals relating to different frequency bands, respectively, in order to condition said signals before transmission in said frequency bands by a wireless communication network. Said PA being used for power amplification in preparation for said transmission and operative with an IBW comprising said frequency bands. Said apparatus(s) is configured to obtain information identifying one or more intermodulation (IM) components outside said frequency bands but within the IBW, which IM components are caused by said PA. Said apparatus(s) is further configured to selectively process said identified IM components as part of said DPD to thereby suppress formation of at least some of said identified IM components, and/or as part of said FF linearization by adding reference signals to said FF linearization, which additional reference signals correspond to at least some of said identified IM components.

The selective processing of identified IM components as part of said DPD and/or said FF linearization, is thus performed to suppress, or at least support suppression of, said identified IM components, which are a form of distortion. More generally, embodiments herein thus supports suppression of distortion caused by the PA. Since the DPD and FF linearization on said multiple digital input signals is example of conditioning of the signals before transmission, embodiments herein provide improvement regarding conditioning of multiple digital input signals relating to different frequency bands, respectively, before transmission in said frequency bands by a wireless communication network.

Moreover, embodiments herein with selective processing of IM components to support suppression of IM components can cost efficiently be based on, or combined with, even integrated with, conventional implementations of DPD and FF linearization.

Hence, thanks to embodiments herein, signal conditioning and linearization can be improved compared to more conventional approaches with DPD and FF, and at the same time resource and cost efficient transmitter system implementations based on combined DPD and FF linearization are possible.

### BRIEF DESCRIPTION OF THE DRAWINGS

Examples of embodiments herein are described in more detail with reference to the appended schematic drawings, which are briefly described in the following.

FIGS. 1A-B show an example of non-contiguous multiband signals for a wideband system.

FIG. 2 is a schematic block diagram for illustrating an example of a conventional DPD architecture.

FIG. 3 is a block diagram schematically depicting a wireless communication network in which embodiments herein may be implemented and utilized.

FIG. 4 schematically shows a general architecture with cascade DPD and FF and that embodiments herein may operate with.

FIG. 5 schematically show exemplary signals at points A-F indicated in the general architecture.

FIG. 6 is a schematic block diagram illustrating an example of a DPD architecture relevant for some embodiments and an Architecture #1 case described in relation to the general architecture.

FIG. 7 shows spectrums from measurements from examples with and without application of a solution based on embodiments herein.

FIG. 8 is a schematic block diagram illustrating an example of a DPD architecture relevant for some embodiments and an Architecture #2 case described in relation to the general architecture.

FIGS. 9A-C are flowcharts schematically illustrating embodiments of a method according to embodiments herein.

FIG. 10 is a schematic block diagram for illustrating embodiments of how one or more apparatuses may be configured to perform the method and actions discussed in connection with FIG. 9

FIG. 11 is a schematic drawing illustrating some embodiments relating to computer program(s) and carriers thereof to cause the apparatus(es) to perform said method and related actions.

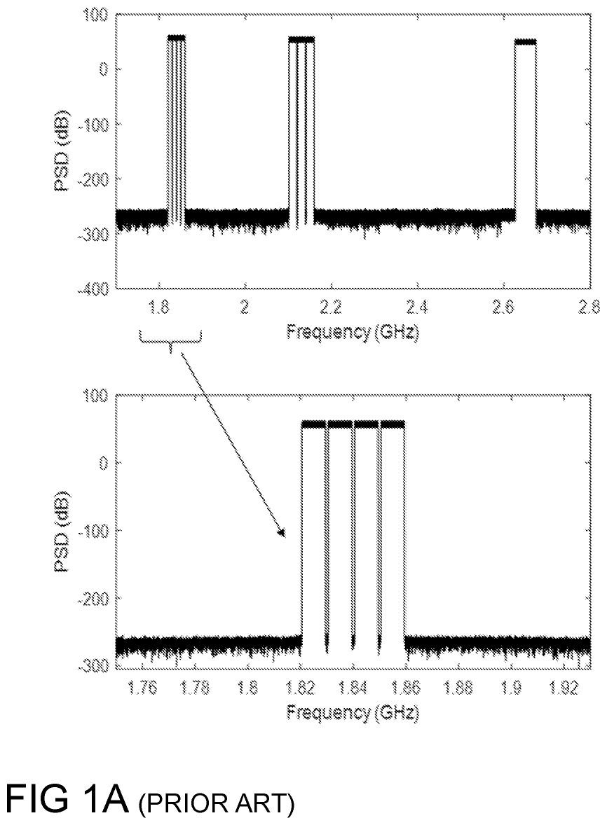

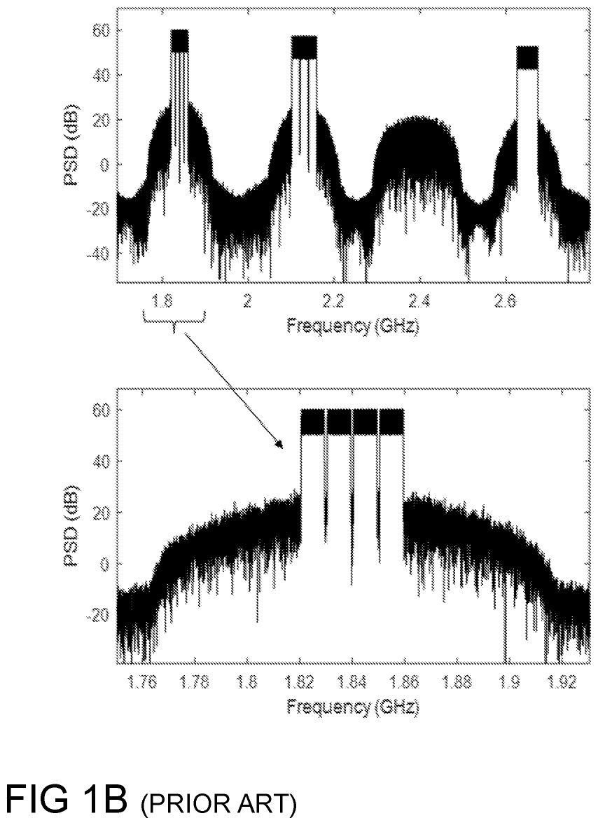

### DETAILED DESCRIPTION

Throughout the following description similar reference numerals may be used to denote similar elements, units, modules, circuits, nodes, parts, items or features, when applicable. Features that appear only in some embodiments are, when embodiments are illustrated in a figure, typically indicated by dashed lines.

Embodiments herein are illustrated by exemplary embodiments. It should be noted that these embodiments are not necessarily mutually exclusive. Components from one embodiment may be tacitly assumed to be present in another embodiment and it will be obvious to a person skilled in the art how those components may be used in the other exemplary embodiments.

As part of the development of embodiments herein, the situation indicated in the Background will first be further elaborated upon.

Existing low sample rate DPD, also known as frequency selective DPD or separate DPD (S-DPD), focuses on a part of the spectrum mainly adjacent to and including the operating bands to improve Adjacent Channel Leakage Ratio (ACLR). However, the nonlinear characteristics of a Power Amplifier (PA) generates several intermodulation products that fall outside of the bands and often far away from the operating bands. When a conventional S-DPD is applied, it is assumed that all these IM products will be rejected by a cavity filter, putting an extra burden, though fairly insignificant, also on the thermal requirements regarding such filters. Additionally, for conventional use of S-DPD, the assumption is typically that the IM products fall outside of the IBW. However, in wideband systems, some of the IMs fall far away from the bands but still within the IBW and/or in between operating bands. As a result, these IMs will impose an extra burden on the error PA (EPA) used in FF linearization.

For wideband systems with sparse spectrum occupancy, trying to linearize digitally the whole spectrum is not a pragmatic solution because of very high sampling rate requirements. It is a lot more economical to selectively linearize around the bands where useful carriers are located, and leave out-of-band (OOB) IM spectral components non-linearized. This is the idea underlying conventional S-DPD. A conventional S-DPD will thus linearize around the bands carrying carriers, but leaving a considerable amount of OOB IM which will pass through the H PA. In this case, OOB IMs needs to be absorbed by filters otherwise the radio will be polluting the environment. Such system increases thermal requirement of the filters. As used herein OOB refers to bandwidth between (multiple) bands of (multiple) signals to be transmitted in different frequency bands, respectively, in a wideband system, but which OOB is still within the IBW.

With the ongoing technology shift into multiple antenna systems and ultra-wideband radio with said large IBWs, it has been realized that using only either one of DPD and FF as linearization technology will often not be enough. It has e.g. been observed in lab measurements with actual wideband PAs, that DPD “only” is typically not enough to achieve the desired linearization for multiband and wideband radio cases, especially with advanced antenna systems. Standalone FF has similar limitations.

Although both DPD and FF methods as such are well known to the person skilled in the art, it would be beneficial with information on efficient combination, e.g. architectures when both technologies are beneficially combined, and especially for multiband and wideband system where, as indicated above, a single technology may not be enough. Using standalone DPD or FF alone will e.g. typically not provide enough linearization required for multi-antenna radios, such as according to 3GPP requirements, based on e.g. ETSI TS 136.104 for LTE and ETSI TS 138.104 for 5G. Due to high sampling rate requirement, conventional DPD covering the whole spectrum is typically not computationally feasible for a wideband system and to meet requirements like this.

Conventional low sample rate DPD techniques, such as S-DPD, alone typically have difficulties in fulfilling emission requirements. Adding a FF system in addition to the S-DPD will not only help to reduce the OOB components but also further linearizes near the bands, serving its original purpose to improve ACLR. Typical measurements have shown that S-DPD can linearize up to −50 dBc and further 10 dB linearization can be achieved by adding FF taking the overall system ACLR to −60 dBc.

To be able to gain a sufficient effect from both DPD and FF in linearization, it is DPD and FF can be applied in a cascade, i.e. serially, and selectively process identified intermodulation components to support suppression of these. Embodiments herein are based on this and provide improved adjacent channel leakage ratio (ACLR) while enabling reduction of cost and energy consumption, compared to if more conventional application of DPD and FF would be used.

The DPD proposed in embodiments herein is preferably based on S-DPDs as mentioned above. Especially for such architecture where the IM products are suppressed by the DPD, such architecture is beneficial since it easily can be extended with further separate DPDs, i.e. with further S-DPDs or S-DPD subparts, that operate OOB in addition to the conventional S-DPD that would operate only in-band (IB). IB here refers to a linearization bandwidth for the frequency band of a signal to be transmitted.

Embodiments and examples herein are explained in relation to two variants of an example architecture, the variants being referred to as Architecture #1 and Architecture #2.

Architecture #1 may be referred to as cascade of S-DPD with PA inverse IM models & FF. It is based on a modified S-DPD part compared to conventional S-DPD, while the FF part may correspond to a conventional one for FF linearization. Two types of S-DPD subparts are used, IB S-DPDs and OOB S-DPDs. The IB S-DPDs may work as conventional S-DPDs where the goal of IB S-DPDs is to linearize adjacent regions of the operating bands and improve ACLR. A main target of OOB S-DPDs is to suppress high power IMs far away from the operating bands but within the IBW. Together the IB S-DPDs and OOB S-DPDs not only improve ACLR but will also reduce power level requirements for the FF linearization. Cavity filters may be used to reject signals that are outside of the operation bands. Due to the OOB S-DPDs, the output from the PA will have less number of OOB IMs, hence, this architecture also reduces thermal requirements of OOB components suppressed by filters and isolation resistors before passing the signal further on to antenna. The thermal dissipation differences may be insignificant in one antenna branch because the absolute power of the these OOB IMs are quite small. This may make lowering EPA requirements more justified as proposed in Architecture #2, where some OOP IM component(s) are passed through since they are significant to EPA power consumption but insignificant to filters at the antenna.

Architecture #2 may be referred to as cascade of DPD & FF, or S-DPD & FF, with PA forward IM models. It is based on a modified FF part compared to a conventional one while the DPD part may correspond to a conventional one, e.g. S-DPD. The modified FF part corresponds to at a new way of constructing reference signals used in FF. Traditionally, reference signals for FF only contain the operating bands and signals therein. However, in a multiband case, there are several OOB IMs as indicated above. Architecture #2 not only considers the operating bands but also takes into account OOB IMs. This reduces the power of the error signal that the FF needs to amplify.

Before describing embodiments herein further and in greater detail, a wireless communication network will be described for providing a context in which embodiments herein may be implemented and utilized.

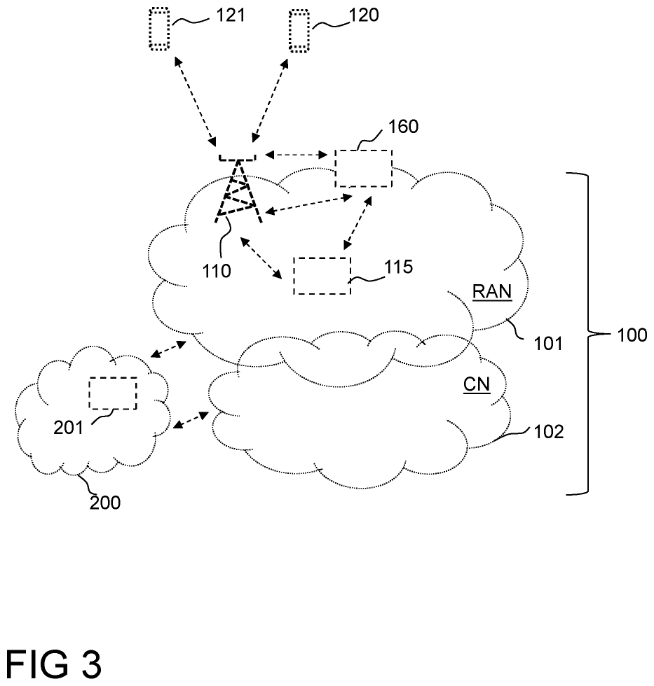

FIG. 3 is a block diagram schematically depicting a wireless communication network 100 in which embodiments herein may be implemented and utilized.

The wireless communication network 100 may comprise a Radio Access Network (RAN) 101 part and a Core Network (CN) 102 part. The wireless communication network 100 may be a telecommunication network or system, such as a cellular communication network that supports at least one Radio Access Technology (RAT), e.g. LTE, or 4G, and/or New Radio (NR) that also may be referred to as 5G, or even further generations.

The wireless communication network 100 typically comprises network nodes that are communicatively interconnected. The network nodes may be logical and/or physical and are located in one or more physical devices. The wireless communication network 100, typically the RAN 101, comprises one or more radio network nodes, e.g. radio network node 110. The radio network nodes are or comprise radio transmitting and/or receiving network nodes, such as base stations and/or are or comprises controlling nodes that control one or more radio transmitting and/or receiving network nodes. The radio network nodes are configured to serve and/or control and/or manage one or more wireless communication devices. Each radio network node provide one or more radio coverages, e.g. corresponding to one or more radio coverage areas, i.e. radio coverage that enables communication with one or more wireless communication devices. A wireless communication device may alternatively be named a wireless device and it may correspond to a UE etc. as mentioned in the Background. Each radio coverage may be provided by and/or associated with a particular Radio Access Technology (RAT). Each radio coverage area may correspond to a so called cell or a radio beam, that simply may be named a beam. As should be recognized by the skilled person, a beam is a more dynamic and relatively narrow and directional radio coverage compared to a conventional cell, and may be accomplished by so called beamforming. A beam is typically for serving one or a few communication devices at the same time, and may be specifically set up for serving one or few communication devices. The beam may be changed dynamically by beamforming to provide desirable coverage for the one or more wireless communication devices being served by the beam. There may be more than one beam provided by one and the same radio network node.

Said radio network nodes may e.g. be communicatively connected, such as configured to communicate, over, or via, a certain communication interface and/or communication link.

Further, the wireless communication network 100, or rather the CN 102, typically comprises one or more core network nodes, that may be communicatively connected to each other and other network nodes, such as configured to communicate, over, or via, a communication interface and/or communication link, with radio network nodes of the RAN 101, e.g. with the radio network node 110.

The figure also shows wireless communication devices 120, 121 for communication with the wireless communication network 100, e.g. by being served by the wireless communication network 100, e.g. by the radio network node 110 when within radio coverage associated with it. Radio communication between wireless communication devices and the radio network nodes of the wireless communication network take part over radio channels between each wireless communication device, e.g. 120, and the radio network node 110.

The figure also shows a further node 201 and a further network 200. The further node 201 may be located outside the wireless communication network 100, i.e. be an external node, as indicated in the figure, or alternatively (not indicated in the figure) be comprised in the wireless communication network 100 and thus be a network node thereof, e.g. a management node thereof. The further network node 201 may in principle be any node communicatively connected to the wireless communication network 100. Likewise, the further network 200 may be located outside the wireless communication network 100, i.e. be an external network, as indicated in the figure, e.g. corresponding to a so-called computer cloud, often simply referred to as cloud, that may provide and/or implement services and/or functions for and/or relating to the wireless communication network 100. The further network 200 may alternatively (not indicated in the figure) be comprised in the wireless communication network 100 and thus e.g. correspond to a subnetwork thereof. It is implied that a network 100 and the further network 200 comprises interconnected network nodes and may e.g. include the further node 201 as indicated in the figure. The further network 200 may in principle be any network communicatively connected to the wireless communication network.

Embodiments herein, and DPD in general, are typically performed by a radio network node, e.g. base station, such as the radio network node 110, but may alternatively e.g. be performed by another network node, e.g. a network node 111, comprised in the wireless communication network 100, connected to a radio network node and that provides data to be transmitted by the radio network node. Such radio network node 111 may be locate in the RAN 101 or in the CN 102

Moreover, shown in the figure is a radio transmit observation receiver (TOR) 160 that may receive radio signals from the radio network node 110 and feedback the received signals in digital format to the network 100 and e.g. the radio network node.

Attention is drawn to that FIG. 3 is only schematic and for exemplifying purpose and that not everything shown in the figure may be required for all embodiments herein, as should be evident to the skilled person. Also, a wireless communication network or networks that correspond(s) to the wireless communication network 100, will typically comprise several further network nodes, such as further radio network nodes, e.g. base stations, network nodes, e.g. both radio and core network nodes, etc., as realized by the skilled person, but which are not shown herein for the sake of simplifying.

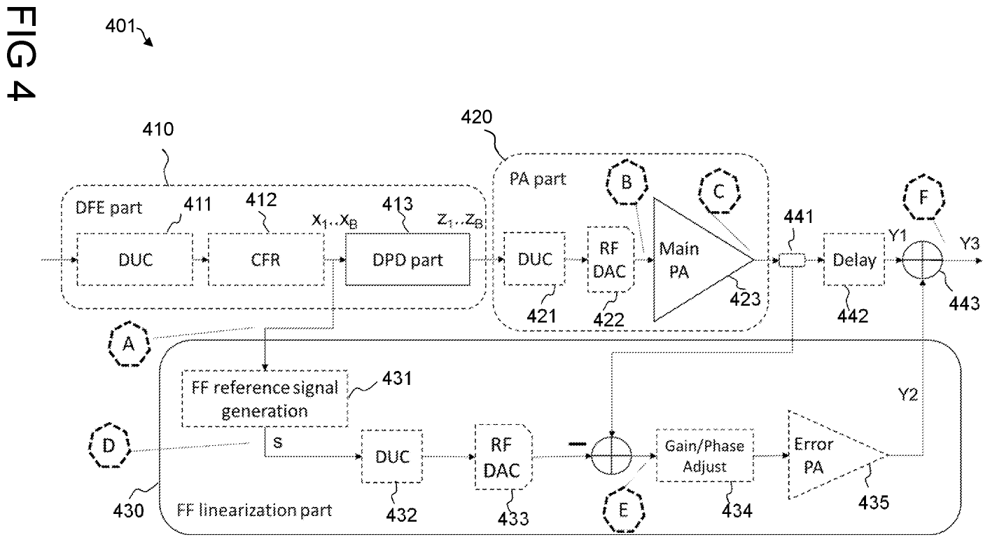

FIG. 4 schematically shows a general architecture with cascade DPD and FF and that embodiments herein may operate with. The architecture will be used as a reference and example when solutions according to embodiments herein are discussed below. The shown architecture may be comprised in or may correspond to a multiband transmitter or transmitter system 401.

The transmitter system 401 comprises a digital front end, or DFE, part 410, a FF linearization part 430 and a power amplification part 420. The DFE part 410 comprises a DPD part 413. The transmitter system 401, or more particularly the DFE part 410, may be configured to receive B different digital input signals with information for transmission in B frequency band respectively. The signals input to the transmitter system 401 may be referred to as baseband signals, digital data from the baseband, or similar. The B different input signal may be non-contiguous multiband signals within a IBW for a wideband system, e.g. IBW>1 GHz.

The signals are typically first upconverted by a digital upconverter (DUC), here a DUC 411. Digital up-sampling is here typically done to increase available space at either end of the spectrum. Reason it that the digital data typically is transmitted to the DFE usually via optical or electrical cables. Typically a 20 MHz radio signal would be sent to the radio at a rate of 30.72M samples per second, a 100 MHz signal would usually be sent at 122 Msp/s. In the 20 MHz case the sample rate can theoretically be used to send signals from −15 MHz to +15 MHz but in practice is often used −10 to +10 MHz or 20 MHz total bandwidth. Hence, there is 5 MHz of unused signal space at either end of the spectrum, which the up-sampling may be performed to utilize.

The signals are thereafter typically subjected to Crest Factor Reduction (CFR), represented by a CFR block 412 in the figure. As known to the skilled person, CFR is a process of reducing the size of the peaks compared to the average value of the signal and thus improving the average power of the signal. As CFR is a form of signal distortion it is beneficially performed after up-sampling so that the distortion products can fit into the extra space created by the up-sampling. CFR typically also includes some filtering to limit the bandwidth of the distortion. CFR may e.g. double the efficiency of a power amplifier later used for the transmission. Any one of prior art CFR methods may be used. Embodiments herein are not dependent on CFR or any particular CFR method.

The signals are then subjected to DPD, in the figure illustrated by a DPD part 413. The digital signals input to the DPD are in examples herein in named x₁ . . . x_{B}, i.e. in case of signals in B bands, there is one signal per band input to the DPD. The general principle and function of DPD are known to the skilled person and have also been discussed above. In short, the DPD attempts to model non-linearities of the PA that the signals will be subjected to before transmission and thereby be distorted. The functional idea of the DPD is to apply the inverse function of the non-linearities to the signal(s) so that there will be cancellation when the PA and the actual non-linearities are applied. Since DPD as such is a distortion as well, although controlled, there may be an extra digital upconversion between the CFR and the DPD, although not shown here. Detailed examples regarding the DPD part 413 for different embodiments herein are discussed below. The predistorted signals output from the DPD part 413 are herein named z₁ . . . z_{B} and corresponds to predistorted versions of x₁ . . . x_{B}, respectively. Note that in some embodiments, corresponding to Architecture #1, there are also signals u₁ . . . u_{K} from the DPD part 413, one per DPD for suppressing IM components, e.g. K IM components, as explained in further detail below.

The output of the DPD part 413 is input to a PA part 420, that alternatively may be named Radio Front End. The signals input to the PA part 420 are typically first digitally upconverted, here represented by a DUC 421 and then follows radio frequency digital to analogue conversion, here by a RF DAC 422. Also other solutions for this are possible, as recognized by the skilled person. For example, the same result could be achieved with conventional DAC's and mixers. However, it is typically most convenient to use RF DAC when dealing with multi band signals.

The PA, or HPA, for power amplification of the signals before transmission is here named main PA 423, to distinguish it from another PA used in FF linearization described next.

The figure also shows a FF linearization part 430 that, as recognized by the skilled person, basically works as conventional FF linearization. However, a difference manifests in some embodiments corresponding to Architecture #2, mentioned above and further discussed below. In these embodiments, the difference is introduced by a FF reference signal generation block 431, further described below. In embodiments where the FF linearization part 430 may operate conventionally only, e.g. in embodiments corresponding to Architecture #1 mentioned above and further discussed below, there may simply be considered to be a bypass of the FF reference signal generation block 431 in the figure.

The general principle and function of FF linearization are known to the skilled person and have also been discussed above. In short, FF linearization is a form of linearization where distortions and associated spectral growth is corrected by adding or subtracting an error signal to the PA output after the distortion has occurred. As can be seen in the figure, the signals before the DPD part, i.e. here x₁ . . . x_{B}, are used as first input signals to, corresponding to reference signals for, the FF linearization. These are then subjected to digital upconversion and radio frequency digital to analogue conversion, in a corresponding manner as the signals after the DPD part, i.e. DUC 432 and RF DAC 433 in the figure may correspond to DUC 421 and RF DAC 422. The output of the RF DAC 433 is thus an analogue signal that is subtracted from the output from the Main PA 423, or rather to power reduced version of this signal via a coupler 441. The resulting signal is present at point E in the figure, which may be referred to as cancellation point. Hence, a difference signal is formed between the signal at the output of the Main PA and at least an analogue version of the signal before the DPD part 413. This difference signal may be referred to as an error signal, that at least corresponds to a portion of a complete error signal. The idea is that the error signal comprises signal content to be cancelled when added at the output of the Main PA 423, i.e. at point F in the figure, which may be after some delay added to the output signal from the Main PA 423, in the figure shown by a Delay block 442. The purpose with the delay is to align the signals from the Main PA 423 and the Error PA so that they combine coherently when added together in summation point 443. The error signal formed at the cancellation point E is typically gain and/or phase adjusted, here by a Gain/Phase adjust block 434, and then power amplified, here by an Error PA 435. The latter is to match the power of the error signal with the power at output of the PA. The purpose of the Gain/Phase adjust block 434 is to adjust the phase and gain slope such that the addition of the (delayed) Main PA 423 output to the Error PA 435 output, at point F, results in the desired cancellation of distortion caused by the Main PA 423. In other words, with reference to the figure and letters therein, the gain and/or phase adjustment is responsible for making sure that the path C-E-Gain/Phase adjust block 434-Error PA 435-F and the path C-Delay block 442-F have the same gain but differ 180 degrees in phase. The output signal from the Error PA 435, and thus also the output signal from the FF linearization part 430, is thus error signal Y2 indicated in the figure. When this signal is added to signal Y1, the result is output signal Y3 at point F, i.e. the relation may a bit simplified be described as Y3=Y1−Y2, or that the FF linearization part 430 results in that the error signal Y2 is formed and removed from the signal Y1 after the Main PA 423.

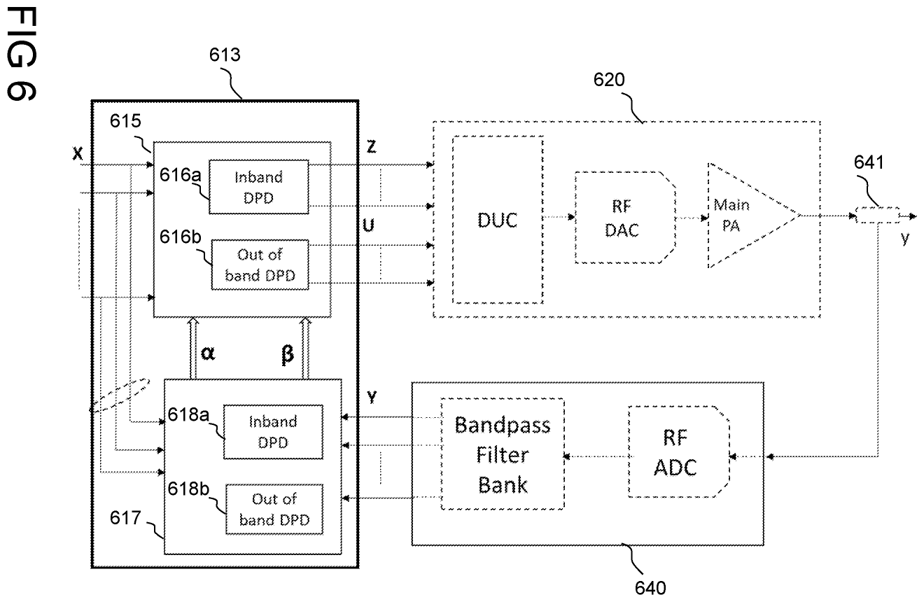

For Architecture #1, the FF reference signal generation block 431 is not used, and can thus be removed or bypassed, and the FF linearization part may operate as conventionally. The DPD part 413 on the other hand is a modified S-DPD part compared to conventional S-DPD, as explained above and further separately discussed below in connection with FIG. 6.

For Architecture #2, the the DPD part 413 may correspond to a conventional S-DPD part. Here however the FF reference signal generation block 431 is being used as explained above and further separately discussed below in connection with FIG. 8.

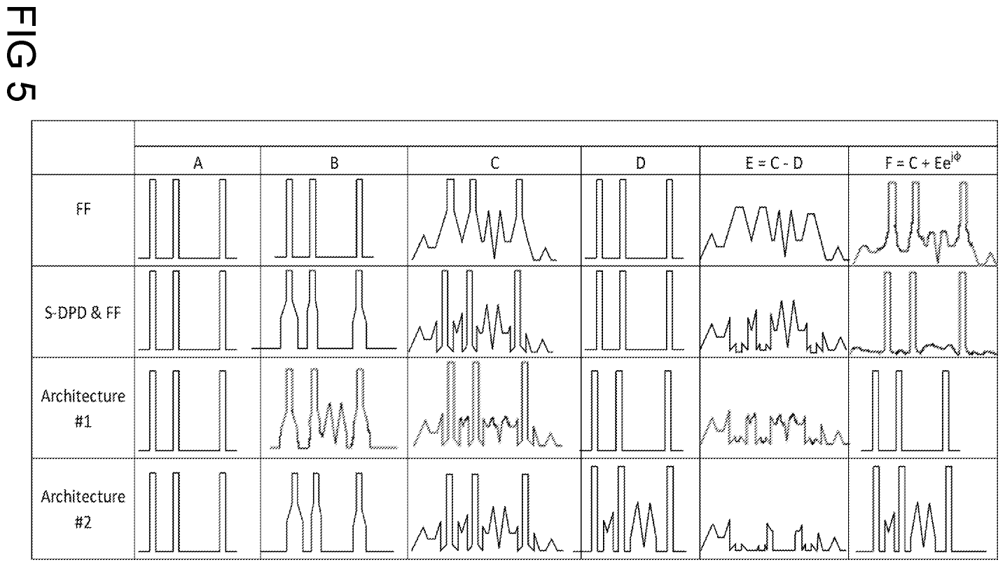

FIG. 5 schematically show exemplary signals at points A-F indicated in the architecture shown in FIG. 4. The signals are shown for 4 different scenarios or cases based on the architecture, viz. for a conventional FF case, a S-DPD & FF case, an Architecture #1 case and an Architecture #2 case, i.e. where the two latter cases are based on Architectures #1 and #2 mentioned above and based on embodiments herein.

In the final column labelled F the effect of the linearization in each case is shown. Note that Architecture #2 appear to produce a worse result with IM products between the operative bands, however, as explained herein, some IM products are here intentionally passed though in a controlled manner, and for later removal by filters.

The first case with the row named “FF” corresponds a standalone FF linearization, i.e. even without DPD and the DPD part 413 in FIG. 4, and is kept in the table only as a reference. The second case and row titled “S-DPD and FF” is when both S-DPD and FF are used, but in a conventional manner. This may be considered to correspond to the “intuitive” way of cascading or using S-DPD and FF together.

Note that in the FF case the FF linearization alone is not able to remove all the OOB contents, e.g. IM products between the operative band, because of their high power content. This result is improved for the case “S-DPD and FF”, but there are still undesirable OOB content spread out between the operative bands.

As can be seen, the cases with Architecture #1, i,e. where high power OOB IM components are selectively suppressed by using extra S-DPD blocks (as described in further detail below), gives a much better final result in column F. This because the FF in this case only need to handle much lower power OOB IM products and thereby can perform better.

In the case with “Architecture #2”, the high power OOB IM components are modelled and presented as reference signals for the FF linearization instead of expecting, or letting, the FF to cancel these components. The output at point F will thus continue to have these high power OOB IM components but can instead be handled by a filter present in a next stage before transmission, i.e. that suppresses these components, and the resulting signal (not shown) for transmission by the antenna, i.e. after said filters, will look similar as the “Architecture 1” at point F.

There are certain advantages and disadvantages associated with Architecture #1 and #2 as explained below and it cannot be said that one architecture always in all circumstances is preferred over the other. What is common, as should be realized, is that both are based on the idea of selectively suppressing OOB components, i.e. OOB distortion, especially components of IM products and particularly such with high power. This enable linearization at desirable levels and also e.g. enable more resource and cost efficient transmitter system implementations based on combined DPD and FF linearization compared to more conventional approaches.

Table 1 below indicates in a comparative manner relative advantages/disadvantages for the last three cases in FIG. 5.

TABLE 1

| | | | | PAPR* of |
|---|---|---|---|---|
| | System | Error PA | Thermal | signal sent |
| | complexity | size | requirements | to HPA |
| S-DPD & FF | Reference | Refer- | Refer- | Reference |
| | | ence(Large) | ence(Low) | |
| Architecture #1 | Medium | Medium | Low | High |
| | | | | (+0.5 dB) |
| Architecture #2 | Medium | Small | Medium | Same as Ref |

*Peak to Average Power Ratio

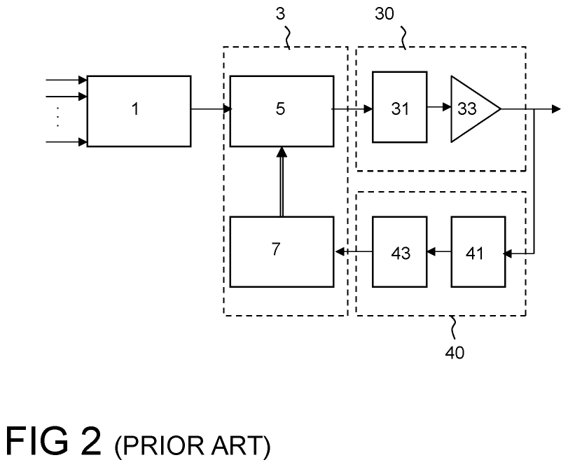

FIG. 6 is a schematic block diagram illustrating an example of a DPD architecture for Architecture #1 described above, i.e. how the DPD part 413 in FIG. 4 may be implemented for the Architecture #1 case. In the figure it is seen a DPD part 613, thus for these embodiments corresponding to the DPD part 413. In the figure is also shown a TOR 640. As is recognized, all DPD implementations involve a TOR for feedback of the output signal from the PA. Hence, a TOR is also implied to be present also in the architecture of FIG. 4, although not explicitly shown. The implied TOR in FIG. 4 may be the same as the TOR 640, and may correspond to a prior art TOR, e.g. the TOR 4 in FIG. 2. The TOR 640 may feedback the Main PA output signal via coupler 641 that may correspond to the coupler 441. Further, the TOR 640 may, e.g. as indicated in the figure, comprise an RF ADC and a bandpass filter bank to accomplish separate feedback signals per band to the DPD part 613, or more specifically to a DPD actuator 615 thereof. The DPD part 613 also comprises a DPD adaptor 617 that, based on DPD input signals x and feedback signals y from the TOR, adapt DPD coefficients, here α and β, to the DPD actuator 615. The coefficients α are for the IB S-DPDs and the coefficients β are for the OOB S-DPDs. Further, as can be seen in the figure and also in correspondence with FIG. 4, input to the DPD part 613, and more specifically to both the DPD actuator 615 and the DPD adaptor 617, are the digital signals x₁ . . . x_{B} associated with said B different frequency bands, respectively. Note that several separated digital signals of the same type but e.g. belonging to, or being associated with different frequency band or regions, such as in the case with x₁ . . . x_{B}, are in the figure and herein indicated by bold letters, i.e. x₁ . . . x_{B} are thus denoted x, corresponding to an array or vector. Matrices may contain several signals as well and may in the following also be indicated by bold letters. Hence, the outputs from the TOR, that are input to the DPD adaptor 617, are denoted y and comprise signals y₁ . . . y_{B} that contain components both from z and u.

Further, as can be seen in the figure, the DPD part 613, and thus each of the DPD actuator 617 and the DPD adaptor 615, contains a separation of in band (IB) DPD and out of band (OOB) DPD, which can be seen as the DPD is in two parts, one for IB and one for OOB. More particularly, the DPD actuator 615 comprises an IB DPD actuator 616a and an OOB DPD actuator 616b, and the DPD adaptor 617 comprises an IB DPD adaptor 618a and an OOB DPD adaptor 618b.

In practice the IB DPD here corresponds to S-DPDs and the OOB DPD corresponds to OOB S-DPDs, since S-DPDs as mentioned above are used, i.e. so that there is a separate DPD, i.e. S-DPD, per band or frequency region to be taken care of by the IB DPD or OOB DPD. The in band part may operate in a conventional manner with one S-DPD per input signal, here x₁ . . . x_{B}, and thus one S.DPD per frequency band 1 . . . B. As already indicated, the OOB S-DPDs are instead typically one per IM component with associated frequency band. As should be realized from the above, OOB refers to that these DPDs operate outside the B frequency bands associated with the signals input to the DPD, here x₁ . . . x_{B}, but should be within the IBW comprising said bands. Note that each one of the S-DPDs involved, and both for the in band and OOB DPDs, may operate on all input signals x₁ . . . x_{B} and for the DPD adaptor on all signals y₁ . . . y_{B}. In the DPD adaptor case, the input signals x are reference data and the TOR signals y are observed output for the adaptation, which is similar to a conventional case. As visualized in the figure, the output from the IB DPD actuator part 616a are said z₁ . . . z_{B} or z, signals, i.e. as in a conventional case with S-DPD, but additionally there is now also output for OOB DPD, in the figure denoted u, i.e. output from the OOB S-DPDs of the OOB DPD actuator part 616b.

In the following it will be shown how the DPD part 613 can be constructed with PA inverse IM models for the OOB S-DPDs. As already indicated, the proposed solution comprises two parallel stages. A first stage corresponds to said IB DPD, or IB S-DPDs, that pre-distorts the input signals x₁ . . . x_{B} and the focus of this stage is to linearize operating bands of the spectrum. The second stage corresponds to said OOB DPD, or OOB S-DPDs, and concentrates on the intermodulation products that appear in the spectrum outside of the B operating bands, but that still may be within IBW. For OOB S-DPDs, it is of interest to suppress particularly high power intermodulation products that fall within the IBW. These IM products are typically away from the operating band and hence the IB DPD cannot be used to linearize this art. Below IB & OOB S-DPDs are described in some detail and exemplified, using memory polynomial. However, as should be realized by the skilled person, one can easily extend this to e.g. generalized memory polynomial or other variants of the Volterra series.

IB S-DPD actuators only focus on the operating bands and corresponding linearization bandwidth. As above, B is used in the following to denote the number of operating bands. As a result, there is B number of IB S-DPD actuators in e.g. the DPD part 615, where each S-DPD only linearizes the adjacent part of its corresponding operating frequency. Typically, these S-DPDs only linearize up to 5 times the bandwidth for efficient implementation. Below, input samples are denoted by xₗ(n) and outputs from the IB S-DPD are denoted by zₗ(n). n represents time-index and l∈(1, B) refers to the band index. P represents the maximum non-linear order of the S-DPD. Memory taps are denoted by the set [symbol] ={Q₀, Q₁, Q₂, . . . Q_{M}} with Q₀=0. As such, the cardinality of [symbol] is M+1.

Output from the IB S-DPD can be written as follows:

zₗ(n)=xₗ(n)+Σₘ₌₀^{M}xₗ(n−Qₘ)Σₚ_{₁}₌₀^{P-1}Σₚ_{₂}₌₀^{p}^{₁} . . . Σₚ_{_{B}}₌₀^{p}^{_{B−1}}α_{l,m,p}_{₁}_{,p}_{₂}_{, . . . ,p}_{_{B}}Π_{b=1}^{B}|x_{b}(n−Qₘ)|^{(p}^{_{b}}^{-p}^{_{b+1}}⁾ (Eq. 1)

Here, α_{l,m,p}_{₁}_{,p}_{₂}_{, . . . ,p}_{_{B}} denotes S-DPD coefficients and
p₁=(0, (P−1)), with the restriction p_{b+1}∈(0, p_{b}) and p_{B+1}=0. Equation (1) describes that the non-linear modelling of the inverse of PA i.e. pre-distortion that can be performed by considering the current sample and past samples. Past samples are included because of memory effects inherent in electronic devices. The nonlinearity of the device creates intermodulation frequencies and that is depicted by B multiplicative terms and exponents p_{b}. When memory and non-linearities both are absent, Equation 1 would become simpler i.e., zₗ(n)=xₗ(n).

In the following it is assumed that there are K numbers of out of band intermodulation products, or components, referred to as OOB IMs in the following for simplicity, that should be suppressed. Hence, it should be constructed K numbers of OOB S-DPDs. Below, uₖ(n) is used to denote the output from the k-th OOB S-DPD. \tilde{P} and \tilde{M} are used to denote non-linear order and memory taps of the OOB S-DPDs. In practice \tilde{P}<P and \tilde{M}<M. Further, f₁, f₂, . . . , f_{B} are used to denote the center frequency of B bands. The locations of the OOB IMs in the spectrum can be found from the linear combination of the center frequencies and can be expressed as Σₗ₌₁^{B}(vₗ)(fₗ) where vₗ={−\tilde{P}, −(\tilde{P}−1), . . . , 0, . . . (\tilde{P}−1), \tilde{P}}. For instance, in a three band case, it would typically be preferred to suppress OOB IM that falls at f₁−f₂+f₃ in the spectrum. We can rewrite this as v₁f₁−v₂f₂+v₃f₃ where v₁=1, v₂=−1, and v₃=1. After identifying OOB IMs to be suppressed the output from the k-th OOB S-DPD can be written as follows.

uₖ(n)=Σₘ₌₀^{\tilde{M}}Π_{b=1}^{B}|x_{b}(n−Qₘ)|^{|v}^{_{b|}}e^{(jv}^{_{b}}^{∠(x}^{_{b}}^{(n-Q}^{ₘ}⁾⁾Σₚ_{₁}₌₀^{\tilde{P}-Σ|v}^{_{b}}^{|}Σₚ_{₂}₌₀^{p}^{₁} . . . Σₚ_{_{B}}₌₀^{p}^{_{B−1}}β_{k,m,p}_{₁}_{,p}_{₂}_{, . . . ,p}_{_{B}}Π_{b=1}^{B}|x_{b}(n−Qₘ)|^{(p}^{_{b}}^{-p}^{_{b+1}}⁾ (Eq. 2)

Here, β_{k,m,p}_{₁}_{,p}_{₂}_{, . . . ,p}_{_{B}} represents the coefficients for k-th OOB S-DPD. The first part of Equation 2, i.e. Π_{b=1}^{B}|x_{b}(n−Qₘ)|^{|v}^{_{b|}}e^{(jv}^{_{b}}^{∠(x}^{_{b}}^{(n-Q}^{ₘ}⁾⁾, determines the location of the IM. The second part of the equation (2) that is Σₚ_{₁}₌₀^{\tilde{P}-Σ|v}^{_{b}}^{|}Σₚ_{₂}₌₀^{p}^{₁} . . . Σₚ_{_{B}}₌₀^{p}^{_{B−1}}β_{k,m,p}_{₁}_{,p}_{₂}_{, . . . ,p}_{_{B}}Π_{b=1}^{B}|x_{b}(n−Qₘ)|^{(p}^{_{b}}^{-p}^{_{b+1}}⁾ determines the order of the OOB S-DPD. Please note that all the operations are performing on baseband complex signals. As a result, the digital upconverter used will typically have to up sample and rotate the output of the OOB S-DPDs according to their locations.

As already mentioned above, a purpose with the OOB S-DPD is to reduce the power level for the error PA used in the feedforward, e.g. Error PA 435. An effect is also that it relaxes cavity filters' thermal requirements. From an implementation point of view, there are also several further advantages of Architecture #1, such as:
Adaptation rate: Since the outcome of the OOB S-DPD won't impact the error vector magnitude, the adaptation of the coefficients β_{k,m,p}_{₁}_{,p}_{₂}_{, . . . ,p}_{_{B}} can be slower than IB S-DPD coefficients α_{l,m,p}_{₁}_{,p}_{₂}_{, . . . ,p}_{_{B}}.
The complexity of the OOB S-DPD: The OOB S-DPD won't impact on the adjacent channel leakage ratio (ACLR) requirements. As a result, lower order memoryless polynomial can be used for OOB S-DPD.
Parallel implementation: The OOB S-DPD does not depend on the outcome of the IB S-DPD, hence parallel implementation is possible.

To verify a implementation based on Architecture #1, an experimental analysis was made using a wideband PA. In the experiment no FF was used. Three frequency bands with signals was used, i.e. B=3, with band named Band 3, Band 1 and Band 7. The bands having a 20 MHz carrier center at 1830 MHz, 2130 MHz and 2670 MHz respectively. For the case study, the two IMs located at f₁−f₂+f₃ (2370 MHz) and 2f₂−f₁ (2430 MHz) were selected for OOB S-DPD suppression.

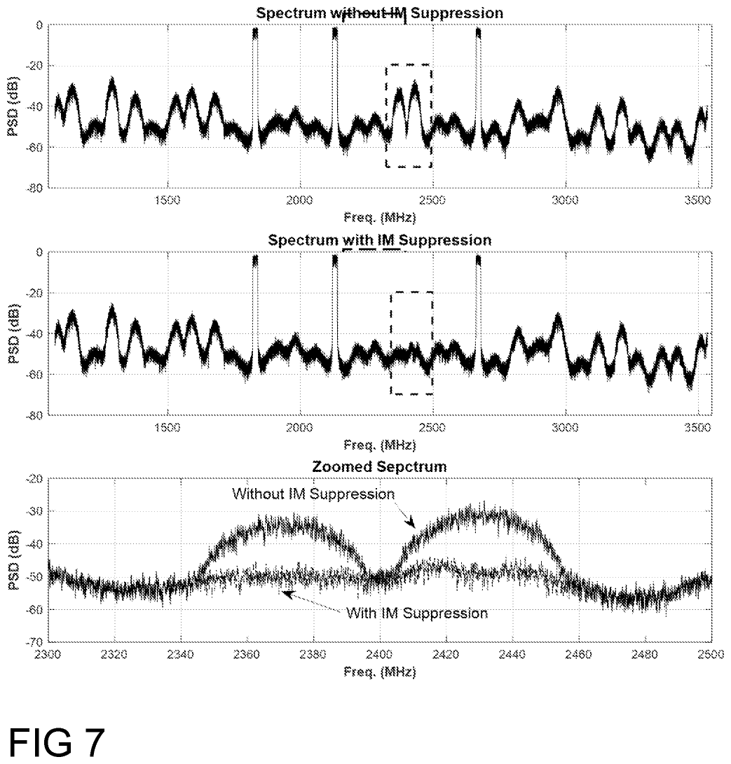

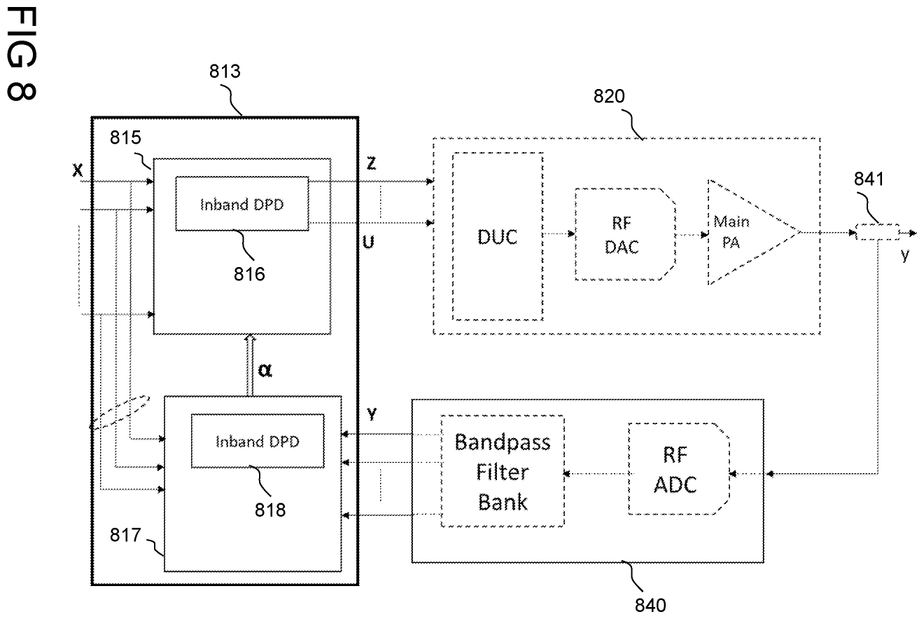

FIG. 7, at the top, shows a spectrum at the PA output without OOB IM suppression, i.e. without any contribution from OOB S-DPDs, only IB S-DPDs. It is very clear that the IMs at 2370 MHz and 2430 MHz are the most two dominant IMs within the IBW. It was used IB S-DPD with 6^{th} order and 4 memory taps to improve the ACLR. The ACLR without DPD was around −34 dBc and after IB S-DPD it became −49 dBc for all the three bands. It was used 245 Msps for the S-DPD actuator and an adaptation rate with 2.4 Gsps sampling rate.

As mentioned, the goal with the OOB S-DPDs are here to suppress dominant IMs within IBW. A 5^{th} order odd-only polynomial was used without memory for the OOB S-DPD. As such, the OOB S-DPDs only requires 4 coefficients per S-DPD and there are two OOB S-DPDs. FIG. 73, in the middle, shows the output of PA with operative presence of also these OOB S-DPDs. FIG. 7, at the bottom, shows a magnified view of the part of the spectrum where the IMs are located and showing the spectrum both from the top and middle view, i.e. without and with the OOB S-DPDs. In comparison with the top view, it can be seen that the signals at 2370 MHz and 2430 MHz are suppressed around 15 dB. ACLR is −49 dBc also in this case.

Some drawbacks associated with the Architecture #1 cases, i.e. with using OOB D-DPDs as described herein:
Digital Upconverter: The OOB S-DPDs when up-sampled and shifted according to their locations in the spectrum, the inclusion of the OOB S-DPDs increases computational requirements in the digital upconverter.
PAPR regrowth: in the experiments, a 0.2-0.5 dB PAPR regrowth was identified when the OOB S-DPDs were included. thereby requiring backoff regarding PA operating point by a similar amount.

Besides the above, the Error PA (EPA), e.g. the Error PA 435, in the FF linearization part still has to handle a large dynamic range (about 10 dB) of error signal although it is less than compared to the simple cascade of S-DPD & FF, such as for the second row in FIG. 5, i.e. with only IB S-DPDs

Architecture #2 on the other hand, enables reduced EPA requirements and makes it more cost and size optimized.

As already mentioned above, in the Architecture #2 case the FF reference signal generation block 431 is part of the architecture shown in FIG. 4, i.e. part of the multiband transmitter system 401. The DPD part 413 may in the Architecture #2 case correspond to a more conventional DPD with only IB DPD, e.g. IB S-DPDs as explained above.

FIG. 8 is a schematic block diagram illustrating an example of a DPD architecture for Architecture #2 i.e. how the DPD part 413 in FIG. 4 may be implemented for the Architecture #2 case. As understood from the above and also realized from comparison of figures, the DPD solution here is similar to the DPD solution as explained above in connection with FIG. 4, but without the OOB DPD and thus only with IB DPD. Hence, in FIG. 8 there is a DPD part 813, corresponding to the DPD part 413 in the Architecture #2 case, a TOR 840, corresponding to the TOR 640. The DPD part 813 comprises a DPD adaptor 817 that, based on DPD input signals x and feedback signals y from the TOR, adapts DPD coefficients, here a, to the DPD actuator 615. The coefficients a are for IB S-DPDs.

In the following, use of the FF reference signal generation block 431, i.e. the Architecture #2 case, is explained. In other words, when the DPD part 413 is composed of just IB DPD as in FIG. 8 and signals are added by the FF Reference Signal Generation block 431. Hence, to the original, e.g. conventional, reference signals for FF linearization, said block adds OOB IM components after modelling the forward PA model. That is, IM components that for Architecture #1, as explained above, instead would be taken care of by the OOB DPD. The choice of how many IMs to model is dependent on multiple factors like the power of IMs, EPA size and computational availability.

The forward model of the IM for a given PA can be established according to the following equation, which is similar to the inverse model as in Equation 2 above.

sₖ(n)=Σₘ₌₀^{M̆}Π_{b=1}^{B}|x_{b}(n−Qₘ)|^{|v}^{_{b|}}e^{(jv}^{_{b}}^{∠(x}^{_{b}}^{(n-Q}^{ₘ}⁾⁾Σₚ_{₁}₌₀^{P̆-Σ|v}^{_{b}}^{|}Σₚ_{₂}₌₀^{p}^{₁} . . . Σₚ_{_{B}}₌₀^{p}^{_{B−1}}γ_{k,m,p}_{₁}_{,p}_{₂}_{, . . . ,p}_{_{B}}Π_{b=1}^{B}|x_{b}(n−Qₘ)|^{(p}^{_{b}}^{-p}^{_{b+1}}⁾ (Eq. 3)

Signals s correspond to the modelled IMs and thus corresponding signals added by the FF generation block 431.

The index k here refers to a selected OOB IM, preferably one observed to be of significant power, and that will form part of the reference signal to reduce EPA size. The number of memory taps M̆ and polynomial order P̆ can be considerably smaller values than if the IMs are modelled with higher accuracy as done usually in DPD, which lower the complexity. As opposed to Equation 2 above, however the signal sₖ(n) shall model the PA and not it's inverse. This differentiation can be made by adapting the coefficients γ_{k,m,p}_{₁}_{,p}_{₂}_{, . . . ,p}_{_{B}}. The adaptation problem can be formulated as in the following equation:

Δγₖ=(R₁^{H}R₁)⁻¹R₁^{H}(Yₖ) (Eq. 4)

The update to the model coefficients for k^{th} IM is denoted by γₖ and is a vector of size

$${N}_{γ} = \frac{{M}^{⌣}}{( {P}^{⌣} - 1 ) !} {\prod }_{r = 1}^{B} ( {P}^{⌣} - 1 + r ) .$$

The matrix R is the correlation matrix formed from input signals from each band, and the Yₖ is IM signals captured and filtered from the output of TOR similar as in FIG. 6 done for OOB S-DPD.
The FF reference signal Z_{FF}_{_{ref}}(n) is formed by upconversion of input signals xₗ(n) and generated IM signals sₖ(n) and can be formulated as in the following equation, where K_{IM} denotes the numbers of IMs considered around frequencies ωₖ.

Z_{FF}_{_{ref}}(n)=Σₗ₌₁^{B}xₗ(n)e^{iω}^{ₗ}^{t}+Σₖ₌₁^{K}^{_{IM}}sₖ(n)e^{iω}^{ₖ}^{t} (Eq. 5)

As should be realized, the solutions explained above, corresponding to Architecture #1 and Architecture #2, are suitable for multi-band advance antenna systems (MB-AAS) where the emission requirements typically becomes much stricter due to wideband spectrum handling by a single HPA, and often with parallel combinations of multiple such HPAs for the antennas. A single stage solution can typically not achieve the desired or required performance levels and hence a dual-stage, or cascade solution, as above is proposed. Which architecture a practical implementation is best based on, may be case specific and e.g. be determined based on requirements and capability.

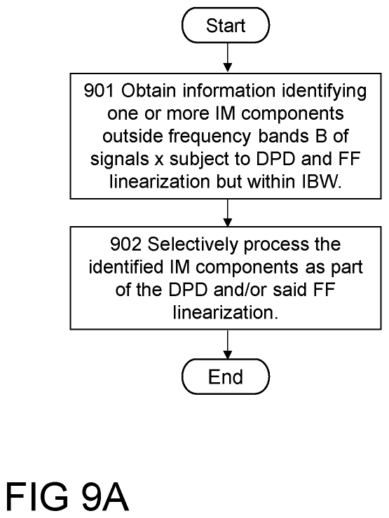

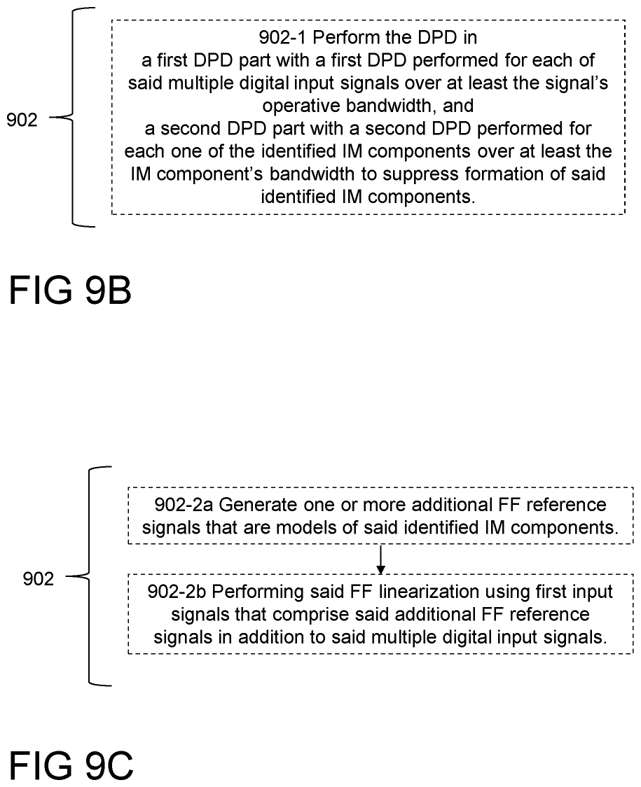

FIGS. 9A-C are flowcharts schematically illustrating embodiments of a method according to embodiments herein. The method is for supporting suppression of distortion caused by a power amplifier, e.g. the Main PA 423, comprised in a transmitter system, e.g. 401, configured to perform DPD and FF linearization on multiple digital input signals, e.g. x1 . . . xB relating to different frequency bands, e.g. 1 . . . B, respectively, to condition said signals before transmission in said frequency bands by a wireless communication network, e.g. 100. The PA being used, or at least being configured to be used, for power amplification in preparation for said transmission and is operative with an IBW, e.g. as explained above, comprising said frequency bands, e.g. 1 . . . B.

There may thus e.g. be B frequency bands as in the above examples. The signals x1 . . . xB, and similar, may below collectively be referred to as single letter, e.g., x, to simplify. The B frequency bands may be non-contiguous, i.e. distributed with substantial frequency spaces in-between, and located within the IBW. The IBW being associated with the PA. The IBW may be categorized as wideband and e.g. in the magnitude of or greater than 1 GHz.

The method may be performed by one or more apparatuses that e.g. may correspond to or be comprised in and/or form such architecture as in FIG. 4, i.e. said apparatus(es) may correspond to the multiband transmitter or the transmitter system 401.

Said apparatus(es) may further e.g. correspond to or be comprised in the wireless communication network 100, or the radio network node 110 or some other suitable network node(s) of the wireless communication network 100.

The actions below that may form the method may be taken in any suitable order and/or be carried out fully or partly overlapping in time when this is possible and suitable.

### Action 901

It is obtained information identifying one or more IM components outside said frequency bands, e.g. 1 . . . B, but within the IBW, which IM components are caused by the PA, e.g. the Main PA 423, and in practise by and/or due to non-linearities of the PA.

Obtain the information may comprise select and/or identify the IM components or receiving said information externally. The IM component(s) may be predetermined or predefined, and/or may be based on a predefined or predetermined criterium or criteria. How many and which IM components that are identified may be based on type, characteristics and/or requirements associated with the FF linearization, e.g. of an error PA used in the FF linearization. Typically at least one or more of the highest power IM components are identified and/or one or more of the lowest order IM components.

In some embodiments, the identified IM component(s) comprise or are one or more of the first order to fifth order IM components. Although there is general applicability to identified IM components, it will in practice typically be beneficial and preferred to at least and/or identify the lowest order IM components, which normally also are those with highest power, and primarily or only let embodiments herein operate on these.

### Action 902

Said identified IM components are selectively processed as part of said DPD and/or said FF linearization. The identified IM components may be selectively processed as part of said DPD and thereby suppress formation of at least some of said identified IM components. The identified IM components may be selectively processed as part of FF linearization by adding reference signals to said FF linearization, which reference signals correspond to at least some of said identified IM components.

The selective processing of identified IM components as part of said DPD and/or said FF linearization is thus performed to suppress, or at least support suppression of, said identified IM components, which correspond to distortion. The method thus supports suppression of distortion caused by the PA.

As explained herein for different embodiments, e.g. related to the Architecture #1 and #2 cases, selective processing of IM components is possible and can be efficiently combined with conventional use of DPD and FF linearization and enable improved conditioning of signals before transmission compared to only conventional DPD and/or FF. Linearization can be improved compared to more conventional approaches and at the same time resource and cost efficient transmitter system implementations based on combined DPD and FF linearization are possible. The selective processing as part of the DPD and/or FF linearization described in further detail below for each case, and has been exemplified in even further details above.

As realized from the present disclosure, in practice, the identified IM components are typically handled by either the DPD or the FF linearization. Which one preferred to use is typically based on case to case specific details, e.g. HW involved in the implementation, what requirements in a practical situation etc. However, in some embodiments one could let some identified IM component(s), e.g. of lowest order and/or or highest power, be processed by either of the DPD or FF linearization, and let some other identified IM components, e.g. of lower order and/or less power, be processed by the other one of the DPD or FF linearization.

### Action 902-1

In some embodiments, said DPD is performed in two parts:

A first DPD part, e.g. comprising IB DPD actuator 616a and the IB DPD adaptor 618a, where a first DPD, e.g. said IB DPD or IB S-DPDs, is performed for each one of said multiple digital input signals over at least the signal's operative bandwidth.

A second DPD part, e.g. comprising OOB DPD actuator 616b and the OOB DPD adaptor 618b, where another, second DPD, e.g. said OOB DPD or OOB S-DPDs, is performed for each one of said identified IM components over at least the component's bandwidth. The second DPD part being arranged to suppress formation of said identified IM components.

In some embodiments, said second DPD is performed as second separate DPDs, i.e. S-DPDs, targeting said identified IM components, respectively, each second S-DPD performing predistortion over its targeted IM component's bandwidth.

In some embodiments, said first DPD is performed as first separate DPDs, i.e. S-DPDs, targeting said multiple digital input signals, e.g. x1 . . . xB, respectively, each first S-DPD performing predistortion over its targeted digital input signal's operative bandwidth.

As should be recognized, the present action may fully or partly correspond to the Architecture #1 case discussed above.

As used herein, by a signal's operative bandwidth is meant a continuous bandwidth that covers a center frequency of the signal and neighbouring frequencies until the signal level has decreased to a predetermined level, e.g. at or below a thermal noise level, such as the thermal noise level of the system. Typically, DPD, and e.g. S-DPD here, is performed over a linearization bandwidth that covers the whole operative bandwidth by a margin that typically is predetermined and substantial, e.g. at least 5 times the operative bandwidth.

As used herein, by a IM component's bandwidth is meant a continuous bandwidth that cover a center frequency of the IM component and neighbouring frequencies until the signal level of the IM component has decreased to a predetermined and/or insignificant level, e.g. at or below a thermal noise level, such as the thermal noise level of the system.

As should be recognized, Action 902-1 may correspond to or be comprised in Action 902 above for some embodiments that e.g. cover the Architecture #1 case mentioned above.

### Action 902-2a

FF reference signals that are models of said identified IM components are generated. An example of such model signals are the signals s in the examples above.

### Action 902-2b

Said FF linearization is performed using first input signals that comprise said additional FF reference signals, e.g. s, in addition to said multiple digital input signals, e.g. x1 . . . xB, thereby supporting, and/or facilitating, suppression of the IM components by filters after said power amplification and prior to said transmission.

The identified IM components will thereby thus pass through the FF linearization similar to the wanted signals, i.e. said multiple digital input signals, e.g. x1 . . . xB. Note that it can be considered implied that FF linearization in a context as for embodiments involve reference signals that correspond to said multiple digital input signals.

The identified IM components are known, each within a known bandwidth corresponding to the bandwidth of the component and can be removed by filters before transmission. In these embodiments, said identified IM components may thus correspond to IM components identified as suitable to be excluded from error power amplification in the FF linearization, and instead be separately suppressed post the FF, e.g. by filters before transmission.

Further, as mentioned above, typically the identified IM components are such that will have highest power after the PA. In particular if these IM components are used as additional reference signals to the FF linearization, the requirements on the FF linearization can typically be relaxed, and hence a less complex, less expensive FF linearization implementation can be used.

Actions 902-2a and 902-2b may correspond to or be comprised in Action 902 above for some embodiments that e.g. cover the Architecture #2 case mentioned above.

In some embodiments, the method above is performed by a multiband transmitter or transmitter system, e.g. the transmitter system 401. Such transmitter system may comprise a a DPD part, e.g. 413, a FF linearization part, e.g. 430, and a power amplification part, e.g. 420. The DPD part may be comprised in a digital front end (DFE) part, e.g. 410, and may be configured to perform said DPD on said multiple digital input signals, e.g. x1 . . . xB, and provide digital intermediate output signals, e.g. y1 . . . yB, respectively. The power amplification part, e.g. 420, may comprise said power amplifier, e.g. 423, and be configured to operate on said digital intermediate output signals, such as y1 . . . yB. The power amplification part may further be configured to provide an intermediate power amplified output signal, e.g. Y1. The FF linearization part, such as 430, may be configured to perform said FF linearization based on first input signals that are reference signals comprising at least said multiple digital input signals, such as x1 . . . xB, and a second input signal that is said intermediate power amplified output signal, such as Y1, and as output provide a power amplified error signal, e.g. Y2. The transmitter system may further be configured to provide a transmission signal, e.g. Y3, based on the intermediate power amplified output signal, e.g. Y1, with removal of the power amplified error signal, e.g. Y2.

As the skilled person should realize and from the previous examples regarding the transmitter system 401, the error signal, e.g. Y2, is a gain an/or phase adjusted and power amplified difference signal, said difference signal being based on the intermediate power amplified output signal, e.g. Y1, with removal of an analogue version, e.g. digital upconverted and RF DAC version, of said first input signals, i.e. the reference signals to the FF linearization. The analogue version may be formed by subjecting the first input signals to corresponding processing, e.g. digital up conversion and RF DAC, as the digital intermediate output signals, e.g. y1 . . . yB, are subjected to by the power amplification part, e.g. 420, before power amplification by the power amplifier. The difference signal is preferably power amplified by an “error” power amplifier, or Error PA, e.g. 435, of the FF linearization part, e.g. 430, thereby forming said power amplified error signal, such as Y2.

As should be realized, digital signals, e.g. x and y, herein may be complex valued signals and/or may correspond to baseband signals that also can be referred to as complex baseband signals or similar.

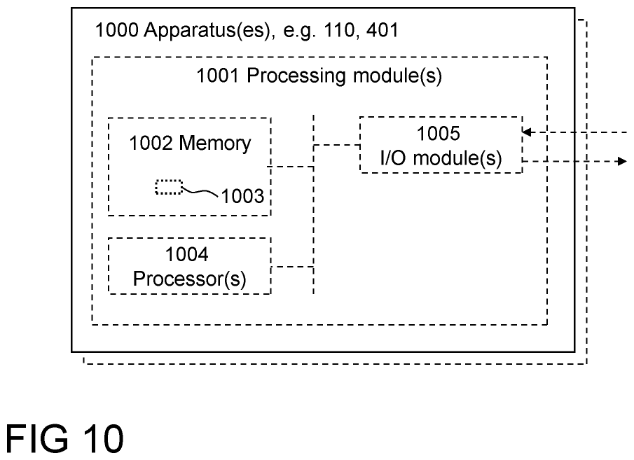

FIG. 10 is a schematic block diagram for illustrating embodiments of how one or more apparatuses 1000 may be configured to perform the method and actions discussed above in connection with FIG. 9. The apparatus(es) 1000 may e.g. correspond to or be comprised in or comprise architecture, transmitter system, or related arrangements, as exemplified and indicated above, e.g. in FIG. 4, 6, 8. Said apparatus(es) may further e.g. be comprised in the wireless communication network 100, or the radio network node 110 or some other network node(s) of the wireless communication network 100, e.g. that provides signals to be used in wireless transmission by the radio network node 110.

Hence, said apparatus(es) 1000 are for supporting suppression of distortion caused by a PA, e.g. PA 423, comprised in a transmitter system, e.g. the transmitter system 401, configured to perform DPD and FF linearization on multiple digital input signals, e.g. x1 . . . xB, relating to different frequency bands, e.g. 1 . . . B, respectively, in order to condition the signals before transmission in said frequency bands by a wireless communication network, e.g. 100. The PA configured to be used for power amplification in preparation for said transmission and operative with an IBW comprising said frequency bands.

The apparatus(es) 1000 may comprise processing module(s) 1001, such as a means, one or more hardware modules, including e.g. one or more processors, and/or one or more software modules for performing said method and/or actions.

The apparatus(es) 1000 may further comprise memory 1002 that may comprise, such as contain or store, computer program(s) 1003. The computer program(s) 1003 comprises ‘instructions’ or ‘code’ directly or indirectly executable by the apparatus(es) 1000 to perform said method and/or actions. The memory 1002 may comprise one or more memory units and may further be arranged to store data, such as configurations and/or applications involved in or for performing functions and actions of embodiments herein.

Moreover, the apparatus(es) 1000 may comprise processor(s) 1004, i.e. one or more processors, as exemplifying hardware module(s) and may comprise or correspond to one or more processing circuits. In some embodiments, the processing module(s) 1001 may comprise, e.g. ‘be embodied in the form of’ or ‘realized by’ processor(s) 1004. In these embodiments, the memory 1002 may comprise the computer program 1003 executable by the processor(s) 1004, whereby the apparatus(es) 1000 is operative, or configured, to perform said method and/or actions thereof.

Typically the apparatus(es) 1000, e.g. the processing module(s) 1001, comprises Input/Output (I/O) module(s) 1005, configured to be involved in, e.g. by performing, any communication to and/or from other units and/or devices, such as sending and/or receiving information to and/or from other devices. The I/O module(s) 1005 may be exemplified by obtaining, e.g. receiving, module(s) and/or providing, e.g. sending, module(s), when applicable.

Further, in some embodiments, the apparatus(es) 1000, e.g. the processing module(s) 1001, comprises one or more of an obtaining module(s), performing module(s), generating module(s), as exemplifying hardware and/or software module(s) for carrying out actions of embodiments herein. These modules may be fully or partly implemented by the processor(s) 1004.

Hence:

The apparatus(es) 1000, and/or the processing module(s) 1001, and/or the processor(s) 1004, and/or the I/O module(s) 2005, and/or the obtaining module(s) are thus operative, or configured, to obtain said information identifying said one or more IM components.

The apparatus(es) 1000, and/or the processing module(s) 1001, and/or the processor(s) 1004, and/or the I/O module(s) 1005, are further operative, or configured, to selectively process said identified IM components as part of said DPD and/or said FF linearization.

In some embodiments, the apparatus(es) 1000, and/or the processing module(s) 1001, and/or the processor(s) 1004, and/or the I/O module(s) 1005, and/or the performing module(s) are operative, or configured, to perform said DPD in said two parts, the first DPD part and the second DPD part.

In some embodiments, the apparatus(es) 1000, and/or the processing module(s) 1001, and/or the processor(s) 1004, and/or the I/O module(s) 1005, and/or the generating module(s) are further operative, or configured, to generate said one or more additional FF reference signals that are models of said identified IM components.

In some embodiments, the apparatus(es) 1000, and/or the processing module(s) 1001, and/or the processor(s) 1004, and/or the I/O module(s) 1005, and/or the performing module(s) are further operative, or configured, to perform said FF linearization using said first input signals that comprise said additional FF reference signals.

In some embodiments, said apparatus(es) 1000 comprises, and/or may implement, said DPD part, e.g. 413, the FF linearization part, e.g. 430, and the power amplification part, e.g. 420, which then may be implemented fully or partly by said processing module(s) 1001, the processor(s) 1004, the I/O module(s) 1005, and/or the further module(s) mentioned. This may be the case when said apparatuses 1000 correspond to or comprise a transmitter system, such as the transmitter system 401.

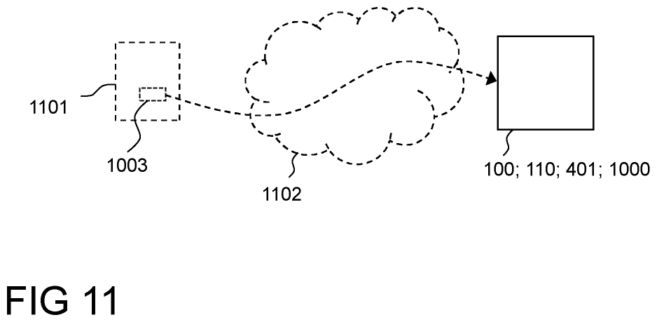

FIG. 11 is a schematic drawing illustrating some embodiments relating to computer program(s) and carriers thereof to cause said apparatus(es) 1000 discussed above to perform said method and related actions. The computer program(s) may be the computer program(s) 1003 and comprises instructions that when executed by the processor(s) 1004 and/or the processing module(s) 1001, cause the apparatus(es) 1000 to perform as described above. In some embodiments there is provided carrier(s), or more specifically data carrier(s), e.g. computer program product(s), comprising the computer program(s). Each carrier may be one of an electronic signal, an optical signal, a radio signal, and a computer readable storage medium, e.g. a computer readable storage medium or media 1101 as schematically illustrated in the figure. The computer program(s) 1003 may thus be stored on such computer readable storage medium 1101. By carrier may be excluded a transitory, propagating signal and the data carrier may correspondingly be named non-transitory data carrier. Non-limiting examples of the data carrier(s) being computer readable storage medium or media is a memory card or a memory stick, a disc storage medium, or a mass storage device that typically is based on hard drive(s) or Solid State Drive(s) (SSD). The computer readable storage medium or media 1101 may be used for storing data accessible over a computer network 1102, e.g. the Internet or a Local Area Network (LAN). The computer program(s) 1003 may furthermore be provided as pure computer program(s) or comprised in a file or files. The file or files may be stored on the computer readable storage medium or media 1101 and e.g. available through download e.g. over the computer network 1102 as indicated in the figure, e.g. via a server. The file or files may e.g. be executable files for direct or indirect download to and execution on said apparatus(es) 1000 to make it or them perform as described above, e.g. by execution by the processor(s) 1004. The file or files may also or alternatively be for intermediate download and compilation involving the same or another processor(s) to make them executable before further download and execution causing said apparatus(es) 1000 to perform as described above.

Note that any processing module(s) and circuit(s) mentioned in the foregoing may be implemented as a software and/or hardware module, e.g. in existing hardware and/or as an Application Specific Integrated Circuit (ASIC), a field-programmable gate array (FPGA) or the like. Also note that any hardware module(s) and/or circuit(s) mentioned in the foregoing may e.g. be included in a single ASIC or FPGA, or be distributed among several separate hardware components, whether individually packaged or assembled into a System-on-a-Chip (SoC).

Those skilled in the art will also appreciate that the modules and circuitry discussed herein may refer to a combination of hardware modules, software modules, analogue and digital circuits, and/or one or more processors configured with software and/or firmware, e.g. stored in memory, that, when executed by the one or more processors may make any node(s), device(s), apparatus(es), network(s), system(s), etc. to be configured to and/or to perform the above-described methods and actions.

Identification by any identifier herein may be implicit or explicit. The identification may be unique in a certain context, e.g. in the wireless communication network or at least in a relevant part or area thereof.

The term “network node” or simply “node” as used herein may as such refer to any type of node that may communicate with another node in and be comprised in a communication network, e.g. Internet Protocol (IP) network or wireless communication network. Further, such node may be or be comprised in a radio network node (described below) or any network node, which e.g. may communicate with a radio network node. Examples of such network nodes include any radio network node, a core network node, Operations & Maintenance (O&M), Operations Support Systems (OSS), Self Organizing Network (SON) node, etc.

The term “radio network node” as may be used herein may as such refer to any type of network node for serving a wireless communication device, e.g. a so called User Equipment or UE, and/or that are connected to other network node(s) or network element(s) or any radio node from which a wireless communication device receives signals from. Examples of radio network nodes are Node B, Base Station (BS), Multi-Standard Radio (MSR) node such as MSR BS, eNB, eNodeB, gNB, network controller, RNC, Base Station Controller (BSC), relay, donor node controlling relay, Base Transceiver Station (BTS), Access Point (AP), New Radio (NR) node, transmission point, transmission node, node in distributed antenna system (DAS) etc.

Each of the terms “wireless communication device”, “wireless device”, “user equipment” and “UE”, as may be used herein, may as such refer to any type of wireless device arranged to communicate with a radio network node in a wireless, cellular and/or mobile communication system. Examples include: target devices, device to device UE, device for Machine Type of Communication (MTC), machine type UE or UE capable of machine to machine (M2M) communication, Personal Digital Assistant (PDA), tablet, mobile, terminals, smart phone, Laptop Embedded Equipment (LEE), Laptop Mounted Equipment (LME), Universal Serial Bus (USB) dongles etc.

While some terms are used frequently herein for convenience, or in the context of examples involving other a certain, e.g. 3GPP or other standard related, nomenclature, it must be appreciated that such term as such is non-limiting

Also note that although terminology used herein may be particularly associated with and/or exemplified by certain communication systems or networks, this should as such not be seen as limiting the scope of the embodiments herein to only such certain systems or networks etc.

As used herein, the term “memory” may refer to a data memory for storing digital information, typically a hard disk, a magnetic storage, medium, a portable computer diskette or disc, flash memory, random access memory (RAM) or the like. Furthermore, the memory may be an internal register memory of a processor.

Also note that any enumerating terminology such as first device or node, second device or node, first base station, second base station, etc., should as such be considered non-limiting and the terminology as such does not imply a certain hierarchical relation. Without any explicit information in the contrary, naming by enumeration should be considered merely a way of accomplishing different names.

As used herein, the expression “configured to” may e.g. mean that a processing circuit is configured to, or adapted to, by means of software or hardware configuration, perform one or more of the actions described herein.

As used herein, the terms “number” or “value” may refer to any kind of digit, such as binary, real, imaginary or rational number or the like. Moreover, “number” or “value” may be one or more characters, such as a letter or a string of letters. Also, “number” or “value” may be represented by a bit string.

As used herein, the expression “may” and “in some embodiments” has typically been used to indicate that the features described may be combined with any other embodiment disclosed herein.

In the drawings, features that may be present in only some embodiments are typically drawn using dotted or dashed lines.

As used herein, the expression “transmit” and “send” are typically interchangeable. These expressions may include transmission by broadcasting, uni-casting, group-casting and the like. In this context, a transmission by broadcasting may be received and decoded by any authorized device within range. In case of unicasting, one specifically addressed device may receive and encode the transmission. In case of group-casting, e.g. multicasting, a group of specifically addressed devices may receive and decode the transmission.

When using the word “comprise” or “comprising” it shall be interpreted as nonlimiting, i.e. meaning “consist at least of”.

The embodiments herein are not limited to the above described preferred embodiments. Various alternatives, modifications and equivalents may be used. Therefore, the above embodiments should not be taken as limiting the scope of the present disclosure, which is defined by the appending claims.

1. A method for supporting suppression of distortion caused by a power amplifier, “PA”, comprised in a transmitter system configured to perform digital predistortion, “DPD”, and feedforward, “FF”, linearization on multiple digital input signals relating to different frequency bands, respectively, in order to condition the signals before transmission in the frequency bands by a wireless communication network, the PA being used for power amplification in preparation for the transmission and operative with an instantaneous bandwidth, “IBW’”, comprising the frequency bands, the method comprising:
obtaining information identifying one or more intermodulation, “IM”, components outside the frequency bands but within the IBW, which IM components are caused by said PA; and
selectively processing the identified IM components one or both:
as part of the DPD to thereby suppress formation of at least some of the identified IM components; and
as part of the FF linearization by adding reference signals to the FF linearization, which reference signals correspond to at least a plurality of the identified IM components.

2. The method as claimed in claim 1, wherein the method further comprises:
performing the DPD in two parts:
a first DPD part where a first DPD is performed for each one of the multiple digital input signals over at least the signal's operative bandwidth; and
a second DPD part where another, second DPD is performed for each one of the identified IM components over at least the IM component's bandwidth, the second DPD part being arranged to suppress formation of the identified IM components.

3. The method as claimed in claim 2, wherein the second DPD is performed as second separate DPDs, “S-DPDs”, targeting the identified IM components, respectively, each second S-DPD performing predistortion over its targeted IM component's bandwidth.

4. The method as claimed in claim 3, wherein the first DPD is performed as first separate DPDs, “S-DPDs”, targeting the multiple digital input signals, respectively, each first S-DPD performing predistortion over its targeted digital input signal's operative bandwidth.

5. The method as claimed in claim 1, further comprising:
generating one or more additional FF reference signals that are models of the identified IM components; and
performing the FF linearization using first input signals that comprise the additional FF reference signals in addition to the multiple digital input signals, thereby supporting suppression of the identified IM components by filters after the power amplification and prior to the transmission.

6. The method as claimed in claim 1, wherein the identified one or more IM components comprise one or more of the first order to fifth order IM components.

7. The method as claimed in claim 1, wherein the method is performed by one or more apparatuses comprising a DPD part, a FF linearization part and a power amplification part, wherein the DPD part is configured to perform the DPD on the multiple digital input signals and provide digital intermediate output signals, respectively, wherein the power amplification part comprises the power amplifier and is configured to operate on the digital intermediate output signals and provide an intermediate power amplified output signal, wherein the FF linearization part is configured to perform the FF linearization based on first input signals that are reference signals comprising at least the multiple digital input signals and a second input signal that is the intermediate power amplified output signal, and as output provide a power amplified error signal, wherein the transmitter system is configured to transmit a transmission signal based on the intermediate power amplified output signal with removal of the power amplified error signal.

8. A computer storage medium storing a computer program comprising instructions that when executed by one or more processors causes one or more apparatuses to perform a method for supporting suppression of distortion caused by a power amplifier, “PA”, comprised in a transmitter system configured to perform digital predistortion, “DPD”, and feedforward, “FF”, linearization on multiple digital input signals relating to different frequency bands, respectively, in order to condition the signals before transmission in the frequency bands by a wireless communication network, the PA being used for power amplification in preparation for the transmission and operative with an instantaneous bandwidth, “IBW’”, comprising the frequency bands, the method comprising:
obtaining information identifying one or more intermodulation, “IM”, components outside the frequency bands but within the IBW, which IM components are caused by the PA; and
selectively processing the identified IM components one or both:
as part of the DPD to thereby suppress formation of at least some of the identified IM components; and
as part of the FF linearization by adding reference signals to the FF linearization, which reference signals correspond to at least a plurality of the identified IM components.

9. (canceled)

10. An apparatus for supporting suppression of distortion caused by a power amplifier, “PA”, comprised in a transmitter system configured to perform digital predistortion, “DPD”, and feedforward, “FF”, linearization on multiple digital input signals relating to different frequency bands, respectively, in order to condition the signals before transmission in the frequency bands by a wireless communication network, the PA being used for power amplification in preparation for the transmission and operative with an instantaneous bandwidth, “IBW’”, comprising the frequency bands, the apparatus being configured to:
obtain information identifying one or more intermodulation, “IM”, components outside the frequency bands but within the IBW, which IM components are caused by the PA; and
selectively process the identified IM components one or both:
as part of the DPD to thereby suppress formation of at least some of the identified IM components; and
as part of the FF linearization by adding reference signals to the FF linearization, which reference signals correspond to at least a plurality of the identified IM components.

11. The apparatus as claimed in claim 10, further configured to:
perform the DPD in two parts:
a first DPD part where a first DPD is performed for each one of the multiple digital input signals over at least the signal's operative bandwidth; and
a second DPD part where another, second DPD is performed for each one of the identified IM components over at least the IM component's bandwidth, the second DPD part being arranged to suppress formation of the identified IM components.

12. The apparatus as claimed in claim 11, wherein the second DPD is performed as second separate DPDs, “S-DPDs”, targeting the identified IM components, respectively, each second S-DPD for performing predistortion over its targeted IM component's bandwidth.

13. The apparatus as claimed in claim 12, wherein the first DPD is performed as first separate DPDs, “S-DPDs”, targeting the multiple digital input signals, respectively, each first S-DPD for performing predistortion over its targeted digital input signal's operative bandwidth.

14. The apparatus as claimed in claim 10, further configured to:
generate one or more additional FF reference signals that are models of the identified IM components; and
perform the FF linearization using first input signals that comprise the additional FF reference signals in addition to the multiple digital input signals, thereby supporting suppression of the identified IM components by filters after the power amplification and prior to the transmission.

15. The apparatus as claimed in claim 10, wherein the identified one or more IM components comprise one or more of the first order to fifth order IM components.

16. The apparatus as claimed in claim 10, further comprising a DPD part, a FF linearization part and a power amplification part, wherein the DPD part is configured to perform the DPD on the multiple digital input signals and provide digital intermediate output signals, respectively, wherein the power amplification part comprises the power amplifier and is configured to operate on the digital intermediate output signals and provide an intermediate power amplified output signal, wherein the FF linearization part is configured to perform the FF linearization based on first input signals that are reference signals comprising at least the multiple digital input signals and a second input signal that is the intermediate power amplified output signal, and as output provide a power amplified error signal, wherein the transmitter system is configured to transmit a transmission signal based on the intermediate power amplified output signal with removal of the power amplified error signal.

17. The method as claimed in claim 2, wherein the identified one or more IM components comprise one or more of the first order to fifth order IM components.

18. The method as claimed in claim 2, wherein the method is performed by one or more apparatuses comprising a DPD part, a FF linearization part and a power amplification part, wherein the DPD part is configured to perform the DPD on the multiple digital input signals and provide digital intermediate output signals, respectively, wherein the power amplification part comprises the power amplifier and is configured to operate on the digital intermediate output signals and provide an intermediate power amplified output signal, wherein the FF linearization part is configured to perform the FF linearization based on first input signals that are reference signals comprising at least the multiple digital input signals and a second input signal that is the intermediate power amplified output signal, and as output provide a power amplified error signal, wherein the transmitter system is configured to transmit a transmission signal based on the intermediate power amplified output signal with removal of the power amplified error signal.

19. The method as claimed in claim 3, wherein the identified one or more IM components comprise one or more of the first order to fifth order IM components.

20. The method as claimed in claim 3, wherein the method is performed by one or more apparatuses comprising a DPD part, a FF linearization part and a power amplification part, wherein the DPD part is configured to perform the DPD on the multiple digital input signals and provide digital intermediate output signals, respectively, wherein the power amplification part comprises the power amplifier and is configured to operate on the digital intermediate output signals and provide an intermediate power amplified output signal, wherein the FF linearization part is configured to perform the FF linearization based on first input signals that are reference signals comprising at least the multiple digital input signals and a second input signal that is the intermediate power amplified output signal, and as output provide a power amplified error signal, wherein the transmitter system is configured to transmit a transmission signal based on the intermediate power amplified output signal with removal of the power amplified error signal.

21. The method as claimed in claim 4, wherein the method is performed by one or more apparatuses comprising a DPD part, a FF linearization part and a power amplification part, wherein the DPD part is configured to perform the DPD on the multiple digital input signals and provide digital intermediate output signals, respectively, wherein the power amplification part comprises the power amplifier and is configured to operate on the digital intermediate output signals and provide an intermediate power amplified output signal, wherein the FF linearization part is configured to perform the FF linearization based on first input signals that are reference signals comprising at least the multiple digital input signals and a second input signal that is the intermediate power amplified output signal, and as output provide a power amplified error signal, wherein the transmitter system is configured to transmit a transmission signal based on the intermediate power amplified output signal with removal of the power amplified error signal.
